(19) United States
(12) Patent Application Publication
(10) Pub. No.: US 2016/0240680 A1
(43) Pub. Date: Aug. 18, 2016

(54) SEMICONDUCTOR DEVICE HAVING A SILICON AND GERMANIUM MATERIAL FILLING A CAVITY REGION COMPRISING A NOTCH REGION FORMED WITHIN A SEMICONDUCTOR SUBSTRATE

(71) Applicant: Shanghai Huali Microelectronics Corporation, Shanghai (CN)

(72) Inventors: Fang Li, Shanghai (CN); Yefang Zhu, Shanghai (CN); Kun Chen, Shanghai (CN)

(21) Appl. No.: 14/691,511

(22) Filed: Apr. 20, 2015

(30) Foreign Application Priority Data
Feb. 13, 2015 (CN) 201510079521.5

(51) Int. Cl. H01L 29/78; H01L 29/66; H01L 21/3105; H01L 21/3065; H01L 21/3213

(52) U.S. Cl. CPC H01L 29/7849; H01L 21/3065; H01L 21/32133; H01L 21/3105; H01L 29/66553

(57) ABSTRACT

The present invention is directed to semiconductor processes and devices. More specifically, embodiments of the present invention provide a semiconductor device that comprises a shaped cavity formed from two trench structures, and the shaped cavity is filled with silicon and germanium material. There are other embodiments as well.

### CROSS-REFERENCES TO RELATED APPLICATIONS

The present application claims priority to Chinese Patent Application No. 201510079521.5, filed on Feb. 13, 2015, entitled “SEMICONDUCTOR DEVICE WITH SHAPED CAVITIES FOR EMBEDDING GERMANIUM MATERIAL AND DOUBLE TRENCH MANUFACTURING PROCESSES THEREOF”, which is incorporated by reference herein for all purposes.

### STATEMENT AS TO RIGHTS TO INVENTIONS MADE UNDER FEDERALLY SPONSORED RESEARCH AND DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention is directed to semiconductor processes and devices.

Since the early days when Dr. Jack Kilby at Texas Instruments invented the integrated circuit, scientists and engineers have made numerous inventions and improvements on semiconductor devices and processes. The last five decades or so have seen a significant reduction in semiconductor sizes, a reduction which translates to ever increasing processing speed and decreasing power consumption. So far, the development of semiconductor has generally followed Moore's Law, which roughly states that the number of transistors in a dense integrated circuit doubles approximately every two years. Now, semiconductor processes are pushing toward below 20 nm, where some companies are now working on 14 nm processes. Just to provide a reference, a silicon atom is about 0.2 nm, which means the distance between two discrete components manufactured by a 20 nm process is just about a hundred silicon atoms.

Manufacturing semiconductor devices is thus becoming more and more challenging and is pushing toward the boundary of what is physically possible. Huali Microelectronic Corporation™ is one of the leading semiconductor fabrication companies that has focused on the research and development of semiconductor devices and processes.

One of the recent developments in semiconductor technologies has been utilization of silicon germanium (SiGe) in semiconductor manufacturing. For example, SiGe can be used for manufacturing of a complementary metal-oxide-semiconductor (CMOS) with adjustable band gap. While conventional techniques exist for SiGe-based processes, these techniques are unfortunately inadequate for the reasons provided below. Therefore, improved methods and systems are desired.

### BRIEF DESCRIPTION OF THE DRAWINGS

FIG. 1 is a simplified diagram illustrating a conventional U-shaped cavity for SiGe material.

FIG. 2 is a simplified diagram illustrating a cavity structure according to an embodiment of the present invention.

FIG. 3 is a simplified diagram illustrating a cavity structure filled with SiGe material according to an embodiment of the present invention.

FIGS. 4A-F are simplified diagrams illustrating a processing for manufacturing a cavity structure according to an embodiment of the present invention.

### DETAILED DESCRIPTION OF THE INVENTION

The present invention is directed to semiconductor processes and devices. More specifically, embodiments of the present invention provide a semiconductor device that comprises a shaped cavity formed from two trench structures, and the shaped cavity is filled with silicon and germanium material. There are other embodiments as well.

The following description is presented to enable one of ordinary skill in the art to make and use the invention and to incorporate it in the context of particular applications. Various modifications, as well as a variety of uses in different applications, will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of the present invention. However, it will be apparent to one skilled in the art that the present invention may be practiced without necessarily being limited to these specific details. In other instances, well-known structures and devices are shown in block diagram form, rather than in detail, in order to avoid obscuring the present invention.

The reader's attention is directed to all papers and documents which are filed concurrently with this specification and which are open to public inspection with this specification, and the contents of all such papers and documents are incorporated herein by reference. All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

Please note, if used, the labels left, right, front, back, top, bottom, forward, reverse, clockwise and counter clockwise have been used for convenience purposes only and are not intended to imply any particular fixed direction. Instead, they are used to reflect relative locations and/or directions between various portions of an object.

As mentioned above, there are many challenges as semiconductor processes scale down. Downscaling IC provides many advantages, including reduction in power consumption and increase in computation speed, as electrons travel less distance from one IC component to another. For example, for CMOS devices, as the sizes of various critical dimensions (e.g., size of gate oxide) decrease, the carrier mobility drops quickly, which adversely affects device performance. SiGe technology, when utilized in various applications, can improve device performance by improving carrier mobility.

For certain types of devices and manufacturing processes thereof, SiGe technology can significantly improve device performance. For example, Intel™ explored the usage of SiGe when using a 90 nm process to improve the performance of logic units. As the manufacturing processes moved to 45 nm, 32 nm, and 22 nm, the amount of germanium content increased. In the early SiGe devices, germanium makes up less than 15% of the device. As device size decreases, the amount of germanium increases to 40% or even higher. For example, in a CMOS device, SiGe material is embedded in the source and drain regions. In the past, to increase the amount of embedding of SiGe material, U-shaped and Σ-shaped cavities (sometimes referred to as recesses) have been proposed for embedding the SiGe materials.

As an example, SiGe technology refers to semiconductor devices and processes that utilize SiGe material to improve device performance. For example, SiGe can be used in a heterojunction bipolar transistor (HBT) that offers advantages over both conventional silicon bipolar and silicon CMOS for implementation of communications circuits. Among other features, the use of Ge material in these devices improves device performance. However, SiGe devices and processes have their challenges. Among other things, there are difficulties in growing lattice-matched SiGe alloy on Si. Uniformly growing SiGe at the Si-STI interface is desirable, as it increases the performance of the CMOS device. For example, SiGe processes for manufacturing CMOS and other types of devices may comprise detention of various logic gate patterning, such as 45/40 nm, 32/28 nm, and <22 nm, and it is important to maintain logic gate patterns and geometries.

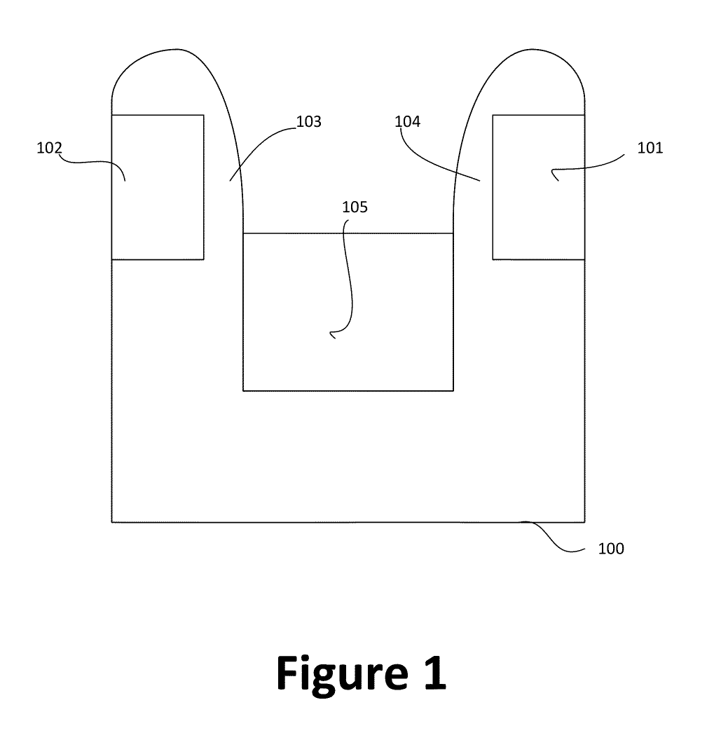

FIG. 1 is a simplified diagram illustrating a conventional U-shaped cavity for SiGe material. A semiconductor substrate 100 comprises a U-shaped cavity for accommodating the filling material 105. For example, the substrate 100 comprises substantially single silicon material. The filling material 105 comprises silicon germanium material. As explained above, with germanium material added to silicon material, carrier mobility and other electrical performance characteristics are improved. For example, the filling material 105 is later used for forming a CMOS device. The semiconductor substrate 100 additionally includes gate materials 101 and 102. For example, the gate materials include metal gate material and/or polysilicon gate material. The gate materials 101 and 102 are protected, respectively, by spacers 103 and 104.

As explained above, an important aspect of the SiGe filling material is its size or volume. Large filling material typically translates to better performance, and it is to be appreciated that embodiments of the present invention increases the cavity size of the substrate, thereby significantly increasing the volume of the SiGe filling material.

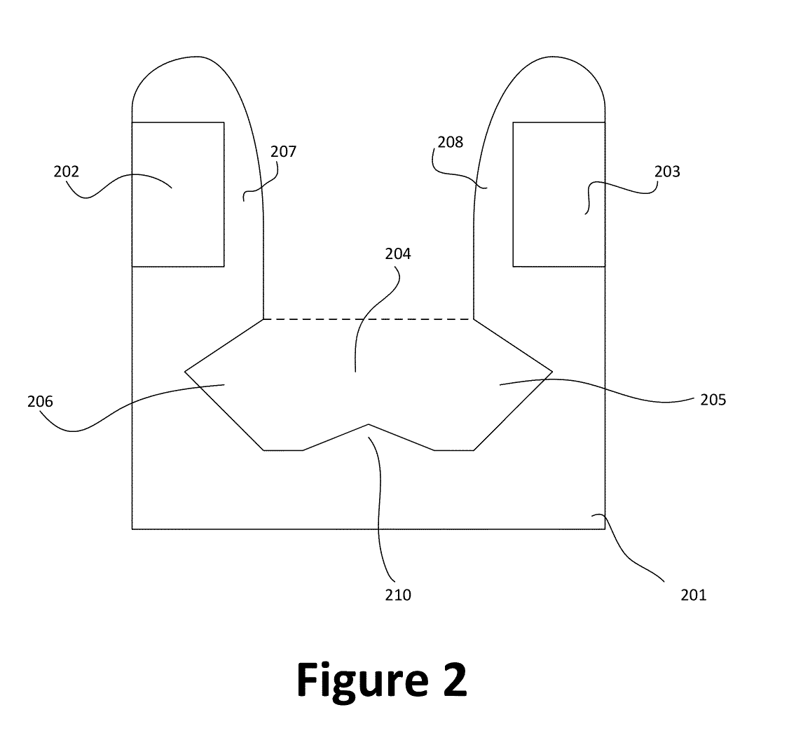

FIG. 2 is a simplified diagram illustrating a cavity structure according to an embodiment of the present invention. This diagram is merely an example, which should not unduly limit the scope of the claims. One of ordinary skill in the art would recognize many variations, alternatives, and modifications. The semiconductor device 200 comprises a substrate 201. For example, the substrate 201 consists essentially of silicon material. For example, the substrate is a part of a silicon wafer. The semiconductor device 200 also includes embedded regions 202 and 203. In certain implementations, regions 202 and 203 comprise polysilicon material. For example, regions 202 and 203 are later processed to form gate regions. In some embodiments, regions 202 and 203 include metal material for forming gate regions. Regions 202 and 203 are protected by spacer 207 and 208. According to various embodiments, spacers 207 and 208 include silicon nitride material. Among other things, the spacers 207 and 208 ensure the opening size of the cavity 204 for embedding the SiGe. For example, the opening size can be up to about 100 nm or greater in some implementations. Depending on the device dimensions, other opening sizes are possible as well. For example, in 20/22 nm (or smaller) processes, the opening sizes might be smaller. Ensuring the opening size of the cavity, among other benefits, makes filling the cavity with the filling material an easy and consistent process. Without the spacers, the opening of the cavity may deform into other shapes (e.g., rounded corners or edges due to etching).

As illustrated in FIG. 1, a cavity for embedding SiGe material is U-shaped in various conventional techniques. It is to be appreciated that the shape of the cavity 204 comprises convex regions 205 and 206, which effectively increases the volume of the cavity 204 and the amount of SiGe material that is later to be filled into the cavity 204. In addition, the cavity 204 includes a concave region 210 extruding from the bottom surface of the silicon substrate 201.

It is to be appreciated that the SiGe material can be deposited into the cavity 204 in various ways, and thus may have a different composition. For example, the SiGe material may include 10% to 50% germanium content. In addition, concentration of the germanium material may vary within the cavity region.

Compared to the Σ-shaped cavity, the shape of cavity 204 provides an increase in volume of about 20% to 30%. The cavity 204 is later filled with SiGe material. Compared to devices with Σ-shaped cavities, a PMOS device with SiGe material filled into the cavity 204 can provide an improvement in PMOS performance of 3% and even greater. In addition to improvements in performance, the cavity shape, according to embodiments of the present invention, can also provide better yield compared to conventional cavity shapes. With a relatively large opening size, the amount of SiGe material filled into the cavity can be effectively controlled. There are other benefits of the cavity shaped illustrated in FIG. 2 according to embodiments of the present invention.

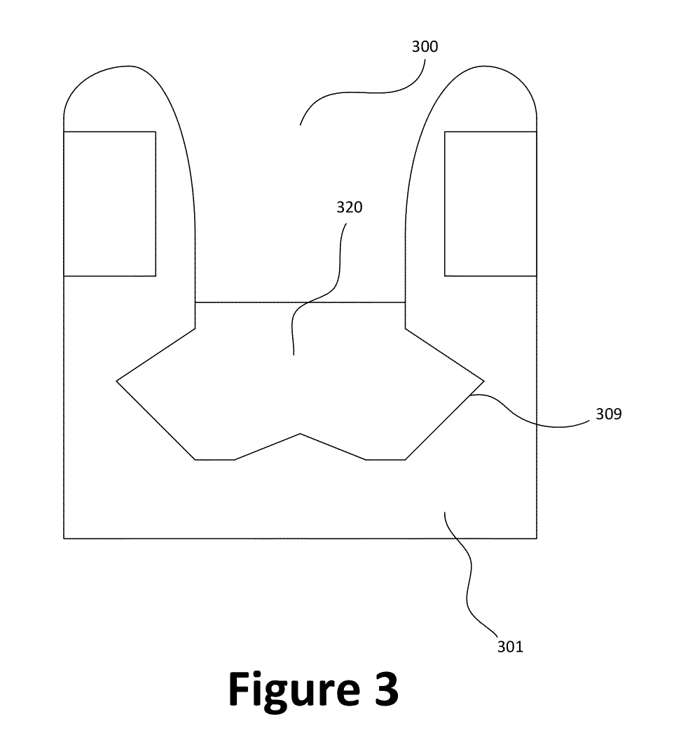

FIG. 3 is a simplified diagram illustrating a cavity structure filled with SiGe material according to an embodiment of the present invention. This diagram is merely an example, which should not unduly limit the scope of the claims. One of ordinary skill in the art would recognize many variations, alternatives, and modifications. As shown in FIG. 3, the semiconductor 300 comprises a filing material 320 filled into the shaped cavity. The filling material 320 comprises silicon germanium (SiGe) material. As explained above, SiGe material embedded in the substrate 301 can improve various electrical characteristics, such as carrier mobility. As illustrated in FIG. 1, a cavity for embedding SiGe material is U-shaped in various conventional techniques. It is to be appreciated that the shape of the cavity 309 comprises convex regions that effectively increase the volume of the cavity 309 and the amount of SiGe material that is later to be filled into the cavity 309.

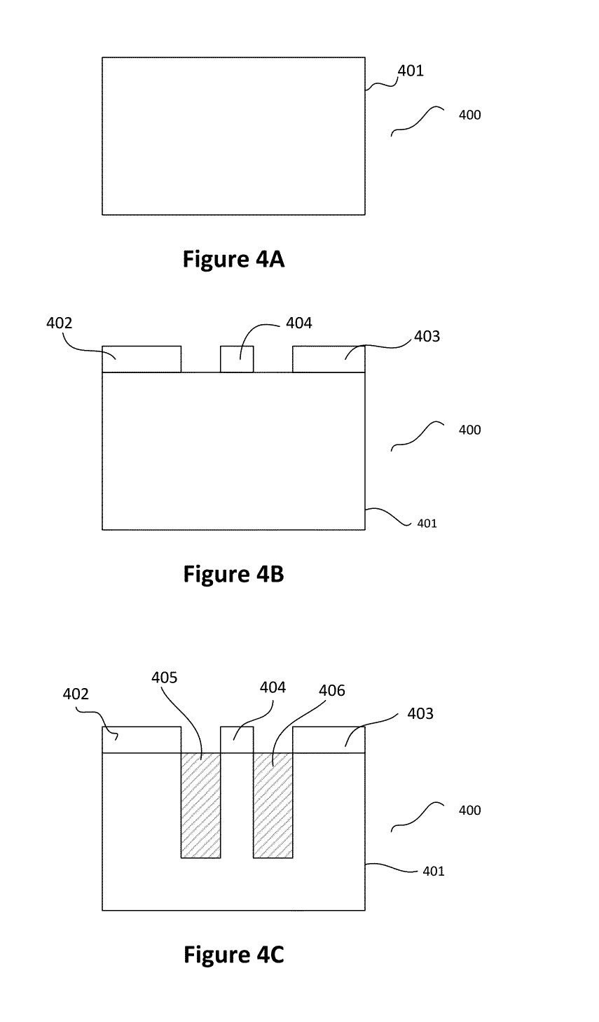

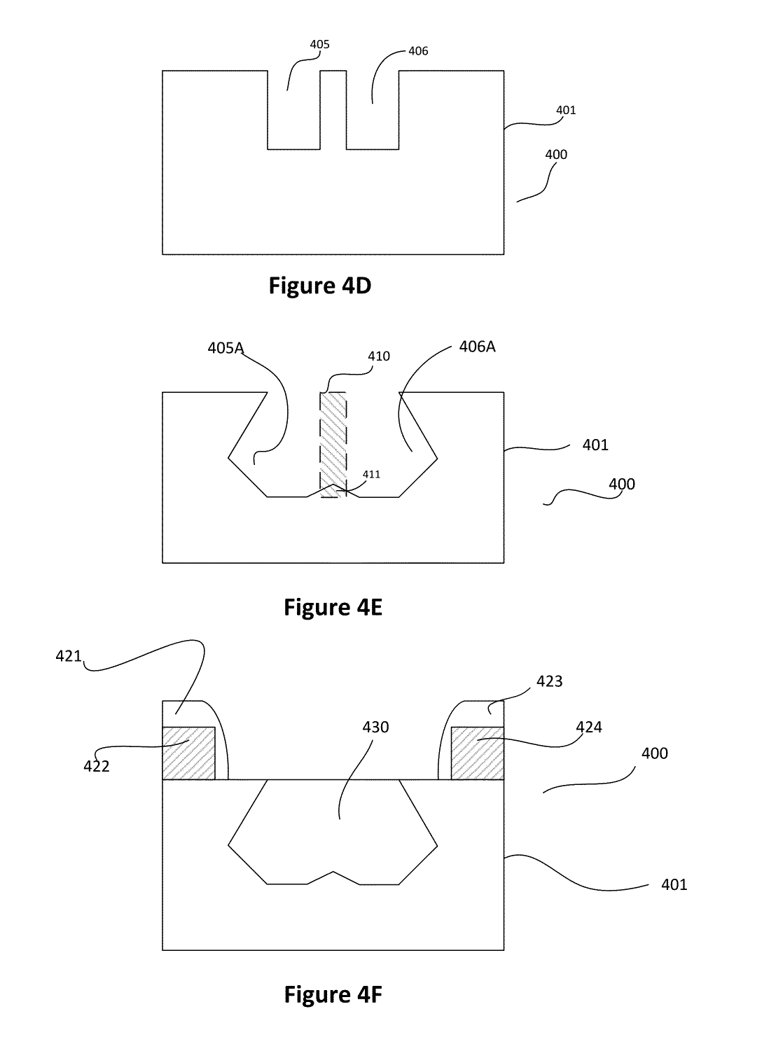

FIGS. 4A-F are simplified diagrams illustrating a processing for manufacturing a cavity structure according to an embodiment of the present invention. These diagrams merely provide an example, which should not unduly limit the scope of the claims. One of ordinary skill in the art would recognize many variations, alternatives, and modifications. For example, various steps illustrated in FIGS. 4A-F can be added, removed, replaced, repeated, modified, rearranged, and/or overlapped, and should not unduly limit the scope of claims.

As shown in FIG. 4A, a silicon substrate 401 is provided to form a semiconductor device 400, which is to be formed. For example, the silicon substrate 400 is a part of a semiconductor wafer, on which a large number of substrates with structures (e.g., cavity) similar to that of the substrate 401 are manufactured. In various embodiments, the silicon substrate 400 is subjected to surface treatment, such as polishing, cleaning, and/or others.

Spacers 402, 403, and 404 are formed, as shown in FIG. 4B. For example, the spacers can be formed by chemical deposition, directional film deposition, and/or other processes. In various embodiments, the spacers comprise silicon and nitrogen material (e.g., SiN). For example, the chemical composition of the spacers is specifically selected to be different from that of the substrate 401, which can stay intact when the substrate 401 materials (e.g., silicon) are etched away to form trenches. In various embodiments, the subsequent etching of the substrate material is performed using hydrogen fluoride (HF) material, and the spacers are chemically resistant to HF.

In various embodiments, the sizes and distances of the spacers are predetermined according to the devices and the cavity to be formed. For example, spacer 404 is characterized by a width of about 10 nm to 20 nm, which defines the distance between the two trenches that are to be formed. In an embodiment, the distance from the spacer 404 is about 40 nm to 50 nm from the spacer 403, which defines the width of the trenches.

FIG. 4C illustrates the trenches 405 and 406 that are to be formed between the spacers, as the spacers define the trench pattern. In various embodiments, direction etching is performed to form the trenches 405 and 406. For example, the trenches 405 and 406 can be formed by plasma etching processes. Defined by the spacers, the trenches can be characterized by a width of about 40 nm to 50 nm and separate by a distance of about 10 nm to 20 nm. It is to be appreciated that depending on the specific implementation and device dimensions, the widths of and the distance between the trenches may be different.

FIG. 4D illustrates a substrate with trenches 405 and 406 formed within the substrate 401. Additionally, spacers 402, 403, and 404 are removed from the substrate. According to certain implementations, spacers are formed for the purpose of facilitating the formation of trenches 405 and 406. Once the trenches are formed, as shown in FIG. 4C, the spacers 402, 403, and 404 are no longer needed and thus are removed. As an example, H₃PO₄ can be used to remove spacers that are made using SiN type of material. Depending on the composition of the spacer material, other types of etchants may be used for the removal of spacers as well. In addition to removing the spacer materials, additional cleaning processes may be performed to remove residues resulting from the etching processes. For example, HF material may be used for performing the cleaning process.

FIG. 4E illustrates the formation of a shaped cavity. In various embodiments, the shaped cavity as shown is formed by performing an etching process through the trenches 405 and 406. More specifically, etchant materials enter through the trenches 405 and 406. For example, a chemical or wet etching process is performed. Depending on the specific implementation, various types of the etchants can be used. In a specific embodiment, Tetramethylammonium hydroxide (TMAH) is used as an etchant, which effectively removes silicon substrate. Depending on the implementation, other types of etchants can be used as well.

During the etching process, one or more etchants, such as TMAH, enter through trenches 405 and 406. For example, during a wet etching process, etchants expand into all directions, both sideways and downward. For example, as a result of etching from both sides of the region 410, the entirety of the region 410 is substantially removed. As explained above, region 410 consists essentially of silicon material that is a part of the substrate 401. The region 410 is a residual region of the substrate after the trenches 405 and 405 are formed. Depending on the amount of etching performed, the region 410 may include a portion that is not completely removed during the etching process. For example, the notched region 411 was a part of the region 410, and since it is at the bottom of the region 410, it is not removed during the etching process. The etchants are specifically selected to be effective in etching away silicon material. As can be seen in FIG. 4E, etchants etch into the sidewalls of the trenches 405 and 406, and thereby create convex cavity shapes 405A and 406A respectively.

It is to be appreciated that the convex cavity structures effectively increase the cavity size, and thereby increase the amount of SiGe material that can be filled into the cavity. For example, compared to the Σ-shaped cavity, the shape of a cavity created by the etching process illustrated in FIG. 4E provides an increase in volume of about 20% to 30%. The cavity is later filled with SiGe material. Compared to devices with Σ-shaped cavities, a PMOS device with SiGe material filled into the shaped cavity can provide an improvement in PMOS performance of 3% and even greater. In addition to improvements in performance, the cavity shape according to embodiments of the present invention can also provide better yield compared to conventional cavity shapes. With a relatively large opening size, the amount of SiGe material filled into the cavity can be effectively controlled.

In addition to improvements in performance, the cavity shape according to embodiments of the present invention can also provide better yield compared to conventional cavity shapes. With a relatively large opening size, the amount of SiGe material filled into the cavity can be effectively controlled. There are other benefits of the cavity shape as well.

Now referring to FIG. 4F. After the shaped cavity is formed, SiGe material 430 is filled into the shaped cavity. Depending on the implementation and the specific needs, the SiGe material 430 may have non-uniform profile. For example, concentration of the germanium material varies within the cavity region, which may be a result of the from gradual deposition of the germanium and silicon material. In certain implementations, chemical vapor deposition processes are used for deposition of the SiGe material into the shaped cavity. Semiconductor device 400 additionally may include addition structures. For example, additional structures such as spacers 421 and 423, and polysilicon embeddings 422 and 424 are formed over the substrate 401. According to various embodiments, the region filled with SiGe material 430 can be used to form a source region or a drain region of a CMOS device.

According to an embodiment, the present invention provides a semiconductor device. The device includes a substrate comprising silicon material. The device also includes a cavity region positioned within the substrate. The cavity region comprises two convex sidewalls and a bottom surface interfacing with the substrate. The bottom surface has a notched region. The device also includes a filling material comprising silicon and germanium material positioned at least partially within the cavity region.

According to another embodiment, the present invention provides a method for fabricating a semiconductor device. The method includes providing a substrate, the substrate consisting essentially of silicon material. The method also includes forming a plurality of spacers overlaying the substrate. The plurality of spacers includes a first spacer, a second spacer, and a third spacer. The first spacer is spaced from the second spacer by a first trench region. The second spacer is spaced from the third spacer by a second trench region. The method further includes performing a first etching process using at least a first etchant to form a first trench at the first trench region and a second trench at the second trench region. The method also includes removing the plurality of spacers. The method includes performing a second etching process using at least a second etchant to form a shaped cavity. The shaped cavity includes two convex regions interfacing with the substrate. The method additionally includes filling the shaped cavity with silicon and germanium material.

While the above is a full description of the specific embodiments, various modifications, alternative constructions and equivalents may be used. Therefore, the above description and illustrations should not be taken as limiting the scope of the present invention which is defined by the appended claims.

1. A semiconductor device comprising:
a substrate comprising silicon material;
a cavity region positioned within the substrate, the cavity region comprising two convex sidewalls and a bottom surface interfacing the substrate, the bottom surface comprising a notched region; and
a filling material comprising silicon and germanium material positioned at least partially within the cavity region.

2. The semiconductor device of claim 1 further comprising a spacer overlaying a top surface of the substrate.

3. The semiconductor device of claim 1 wherein the filling material is characterized by a graduated concentration profile.

4. The semiconductor device of claim 1 further comprising a gate, the semiconductor device being a CMOS device.

5. The semiconductor device of claim 1 wherein the cavity region is characterized by an opening of a diameter of at least 100 nm.

6. The semiconductor device of claim 1 further comprising a drain region at least partially overlapping the filling cavity region.

7. The semiconductor device of claim 1 further comprising a source region at least partially overlapping the filling cavity region.

8. A method for fabricating a semiconductor device, the method comprising:
providing a substrate, the substrate consisting essentially of silicon material;
forming a plurality of spacers overlaying the substrate, the plurality of spacers comprising a first spacer, a second spacer, and a third spacer, the first spacer being spaced from the second spacer by a first trench region, the second spacer being spaced from the third spacer by a second trench region;
performing a first etching process using at least a first etchant to form a first trench at the first trench region and a second trench at the second trench region;
removing the plurality of spacers;
performing a second etching process using at least a second etchant to form a shaped cavity, the shaped cavity comprising two convex regions interfacing with the substrate; and
filing the shaped cavity with silicon and germanium material.

9. The method of claim 8 wherein the second etchant comprises a TAMH material.

10. The method of claim 8 further comprising forming one or more gate regions.

11. The method of claim 8 further comprising forming polysilicon spacer structures.

12. The method of claim 8 wherein the plurality of spacers comprises silicon nitride material.

13. The method of claim 8 further wherein the plurality of spacers is removed using H3PO4┐ material.

14. The method of claim 8 further comprising cleaning the substrate after removing the plurality of spacers.

15. The method of claim 8 further wherein the second spacer material is characterized by a width of about 10 nm to 20 nm.

16. The method of claim 8 further wherein a space between the first spacer and the second spacer is about 40 nm to 50 nm.

17. The method of claim 8 further wherein the first etchant comprises an HF material.

18. The method of claim 8 further comprising performing chemical deposition for forming the plurality of spacers.

19. The method of claim 8 further comprising cleaning a surface of the substrate.
